(19) United States
(12) Patent Application Publication
(10) Pub. No.: US 2012/0149176 A1
(43) Pub. Date: Jun. 14, 2012

(54) METHOD AND APPARATUS FOR FORMING A III-V FAMILY LAYER

(75) Inventors: Chi-Ming Chen, Zhubei City (TW); Chung-Yi Yu, Hsin-Chu (TW); Chia-Shiung Tsai, Hsin-Chu (TW); Ho-Yung David Hwang, Hsinchu (TW)

(73) Assignee: TAIWAN SEMICONDUCTOR MANUFACTURING COMPANY, LTD., Hsin-Chu (TW)

(21) Appl. No.: 12/964,994

(22) Filed: Dec. 10, 2010

(51) Int. Cl. H01L 21/20; C23C 16/34

(52) U.S. Cl. 438/478; 118/719; 257/E21.09

(57) ABSTRACT

Provided is an apparatus. The apparatus includes: a first deposition component that is operable to form a compound over a semiconductor wafer, the compound including at least one of: a III-family element and a V-family element; a second deposition component that is operable to form a passivation layer over the compound; and a transfer component that is operable to move the semiconductor wafer between the first and second deposition components, the transfer component enclosing a space that contains substantially no oxygen and substantially no silicon; wherein the loading component, the first and second deposition components, and the transfer component are all integrated into a single fabrication tool.

### BACKGROUND

The semiconductor integrated circuit (IC) industry has experienced rapid growth in recent years. Technological advances in IC materials and design have produced various types of ICs that serve different purposes. The fabrication of some types of ICs may require forming a III-V family layer on a substrate, for example forming a gallium nitride layer on a substrate. These types of IC devices may include, as examples, light-emitting diode (LED) devices, radio frequency (RF) devices, and high power semiconductor devices.

Traditionally, manufacturers have formed the III-V family layer on a sapphire substrate. However, sapphire substrates are expensive. Thus, some manufacturers have been attempting to form III-V layers on a silicon substrate, which is cheaper. However, existing methods of forming a III-V family layer on a silicon substrate may result in the formation of a gallium oxide material. The gallium oxide material could degrade the properties and the performance of the III-V family layer and is therefore undesirable. Existing fabrication methods have not been able to sufficiently prevent the formation of the gallium oxide material.

Therefore, while existing methods of forming III-V family layers on silicon substrates have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart illustrating a method for fabricating a semiconductor device according to various aspects of the present disclosure.

FIG. 2 is a simplified diagrammatic view of a semiconductor fabrication tool.

FIGS. 3-4 are diagrammatic fragmentary cross-sectional side views of a portion of a semiconductor device at various stages of fabrication in accordance with various aspects of the present disclosure.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. Moreover, the formation of a first feature over or on a second feature in the description that follows may include embodiments in which the features are formed in direct contact, and may also include embodiments in which additional features may be formed interposing the features, such that the features may not be in direct contact. Various features may be arbitrarily drawn in different scales for the sake of simplicity and clarity.

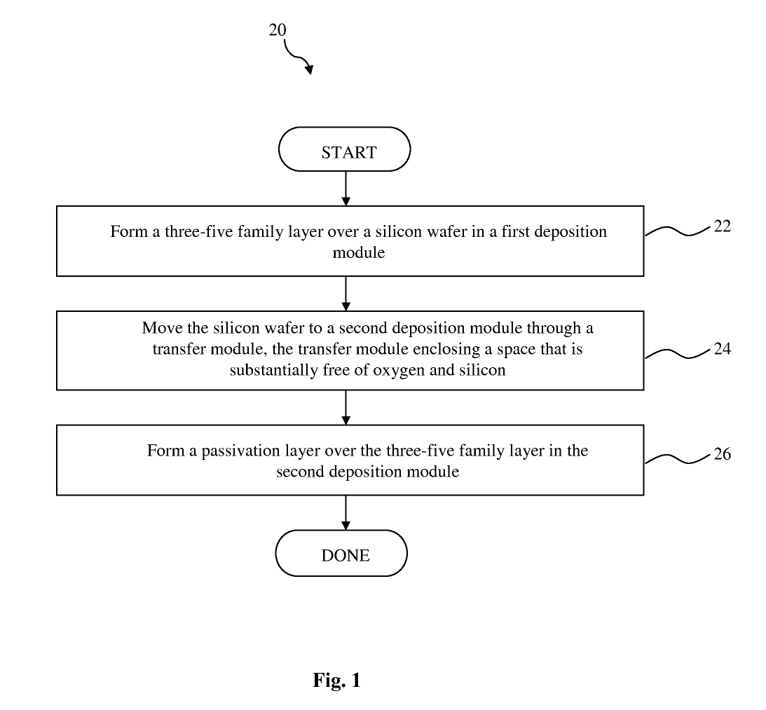

Illustrated in FIG. 1 is a flowchart of a method 20 for fabricating a semiconductor device according to various aspects of the present disclosure. Referring to FIG. 1, the method 20 begins with block 22, in which a III-V family layer is formed over a silicon wafer in a first deposition module. The III-V family layer may include a gallium nitride material. The first deposition module may include a deposition chamber. The method 20 continues with block 24, in which the silicon wafer is moved to a second deposition chamber through a transfer module. The second deposition module may include a deposition chamber. The transfer module encloses a space that is substantially free of oxygen and silicon. The method continues with block 26, in which a passivation layer is formed over the III-V family layer in the second deposition module. The passivation layer may include a dielectric material, such as silicon oxide, silicon nitride, or silicon oxy-nitride.

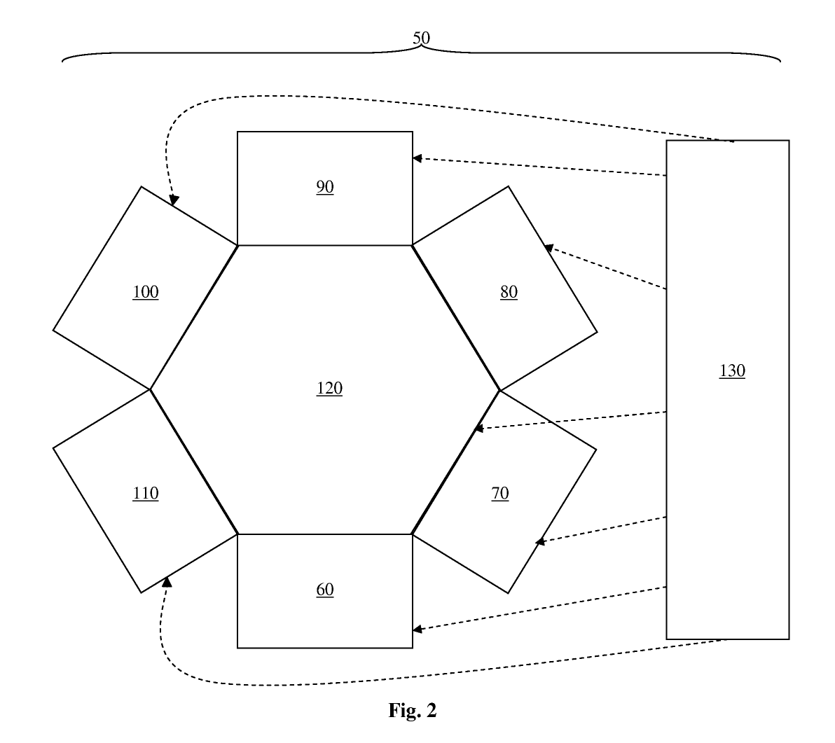

FIG. 2 is a simplified diagrammatic view of a semiconductor fabrication tool 50. The semiconductor fabrication tool 50 is a multi-module cluster tool. The semiconductor fabrication tool 50 includes a plurality of individual processing modules. In the embodiment shown in FIG. 2, the semiconductor fabrication tool 50 includes a loading module 60 (also referred to as a load/unload module), a cleaning module 70, deposition modules 80, 90, 100, 110, and a transfer module 120. These modules 60-120 may also be referred to as components of the semiconductor fabrication tool 50. The semiconductor fabrication tool 50 may also optionally include a central controller 130 that can manage each of the modules 60-120. These components 60-120 and the central controller 130 are all integrated into a single machine according to one embodiment.

In an embodiment, each of the modules 60-120 includes one or more processing chambers. Each processing chamber encloses a space inside the chamber, which can be filled by air or any other type of particular gas. The chambers can be controlled to change their internal gas content, pressure, and temperature. For example, a chamber may be controlled to fill the inside of the chamber with air, or an oxygen gas, or a nitrogen gas. The chamber may set its internal temperature to be within a range from about −50 degrees Celsius to +1400 degrees Celsius (or some other value). The chamber may also set its internal pressure to be anywhere from near a vacuum to a number of times above an atmospheric pressure. The chambers can be individually sealed, so that each chamber can have a different gas content as well as different pressure and temperature settings from other chambers. In other words, what happens inside one chamber has no impact on any of the other chambers of the semiconductor fabrication tool 50.

The loading module 60 serves as an entryway as well as an exit for a semiconductor wafer that is to be processed by the semiconductor fabrication tool 50. For example, a semiconductor wafer (such as a silicon wafer) can be loaded into the semiconductor fabrication tool 50 through the loading module 60. Thereafter, the semiconductor wafer may undergo one or more fabrication processes inside the other modules of the semiconductor fabrication tool 50. When the fabrication processing is complete, the semiconductor wafer is removed (unloaded) from the semiconductor fabrication tool 50 through the loading module 60 again.

The cleaning module 70 is used to clean the semiconductor wafer. The cleaning module 70 may include a plurality of chemicals and solutions that may be used to clean the semiconductor wafer between various fabrication stages.

The deposition module 80 includes a Metal-Organic Chemical Vapor Deposition (MOCVD) chamber according to one embodiment. The MOCVD deposition chamber has the capability to deposit (or grow) a plurality of thin layers that each have a precisely controlled thickness. As a part of the deposition, desired atoms are combined with complex organic gas molecules (whose composition can be varied) and are passed over the semiconductor wafer, which may be heated to a high temperature. The high temperature heat breaks up the molecules and deposits the desired atoms on the surface of the wafer, layer by layer. The deposited layers may have a thickness as thin as a few nanometers. The MOCVD deposition chamber may operate in a substantially vacuum environment. Traditionally, MOCVD deposition chambers are standalone tools. In comparison, the MOCVD deposition chamber is integrated into the semiconductor fabrication tool 50 as a part of a single tool.

In one embodiment, the MOCVD deposition chamber is used to grow a III-V family layer or a III-V family compound over a silicon wafer. A III-V family layer or compound includes an element from the III (three) family of the periodic table and also an element from the V (five) family of the periodic table. The elements from the III family may include boron (B), aluminum (Al), gallium (Ga), indium (In), and titanium (Ti). The elements from the V family may include nitrogen (N), phosphorous (P), arsenic (As), antimony (Sb), and bismuth (Bi). An example of the III-V family layer is gallium nitride (GaN). Thus, the MOCVD deposition chamber can be used to form a thin layer of gallium nitride over a silicon wafer. In other embodiments, the MOCVD deposition chamber may also be used to form thin layers including other materials such as aluminum nitride (AlN), aluminum gallium nitride (AlGaN), gallium arsenide (GaAs), aluminum gallium arsenide (AlGaAs), or other suitable materials.

The deposition module 90 includes a Hydride Vapor Phase Epitaxy (HVPE) deposition chamber according to one embodiment. The HVPE deposition chamber can deposit layers using pure metals as a starting material. For example, liquid gallium can be used as a precursor. The HVPE deposition chamber may operate at or near the standard atmospheric pressure. The layers formed by the HVPE deposition chamber can be formed at relatively fast speeds. For examples, the HVPE deposition chamber may be capable of forming a layer at a rate of hundreds of angstroms per second. In an embodiment, the HPVE deposition chamber may be used to form a gallium nitride layer or an aluminum gallium nitride layer.

The deposition module 100 includes a Plasma-Enhanced Chemical Vapor Deposition (PECVD) chamber according to one embodiment. In general, a plasma is any gas in which a significant percentage of the atoms or molecules are ionized. The plasma is used to enhance chemical reaction rates of precursors used as a part of the CVD process. For example, the plasma causes the reactive gases to decompose via an electrical charge. This causes films or layers to be formed at a lower temperature than that of a traditional CVD process. In an embodiment, the PECVD chamber is used to form a metal layer or a dielectric layer In other embodiments, the PECVD chamber may be used to form other temperature-sensitive layers.

The deposition module 110 includes a Low Pressure Chemical Vapor Deposition (LPCVD) chamber according to one embodiment. The LPCVD chamber operates at a pressure far below the atmospheric pressure. For example, the pressure inside the LPCVD chamber may be only a few Tons, or mili-Torrs, or less. In other words, the pressure inside the LPCVD chamber may approach vacuum. Reduced pressures tend to reduce unwanted gas-phase reactions and therefore improve film uniformity across a wafer. In an embodiment, the LPCVD chamber is used to form layers include silicon oxide, silicon nitride, or silicon oxy-nitride.

The transfer module 120 includes a chamber. The chamber is substantially free of oxygen and silicon. In other words, the oxygen content and the silicon content inside the chamber of the transfer module are both close to zero. For example, the oxygen content may be less than about 15 parts-per-billion (ppb). In an embodiment, the chamber of the transfer module 120 is substantially filled with a nitrogen gas. The pressure inside the chamber is equal to or less than the atmospheric pressure.

The transfer module 120 also include a transfer robot (or an automated wafer handling instrument) that can move wafers around. As is illustrated in FIG. 2, the transfer module 120 is directly coupled to each of the other modules 60-110. The transfer robot moves a semiconductor wafer from one module to another as the wafer undergoes different fabrication processes inside these different modules. For example, a the MOCVD chamber of the deposition module 80 has just been used to form a gallium nitride layer on a silicon wafer. Next, a passivation layer needs to be formed over the wafer inside the deposition module 110. Thus, the transfer robot of the transfer module 120 takes the wafer from the deposition module 80 and sends it to the deposition module 110. The wafer may then undergo the deposition process inside the deposition module 110.

As mentioned above, the semiconductor fabrication tool 50 may also include the central controller 130 that can manage and control the operations of each of the modules 60-120. The central controller 130 may include one or more computers that can be a conventional, commercially-available computers, or any other suitable computer hardware. The hardware may include a processors, controllers, and memory storage devices. The memory storage devices store computer programs that when executed, perform actions including manipulating information, receiving information, storing information, and transferring information. The information may include, for example, commands, process parameters such as those parameters used in the process recipe, measurement data, process data such as the history of processes ran including specific tool or tool sector used and process parameters used, and/or equipment status. The central controller 130 may also include user interfaces that allow users to interface and input commands to the semiconductor fabrication tool 50.

It is understood that the semiconductor fabrication tool 50 may include additional modules that perform different functions. For the sake of simplicity, these additional modules are not discussed herein.

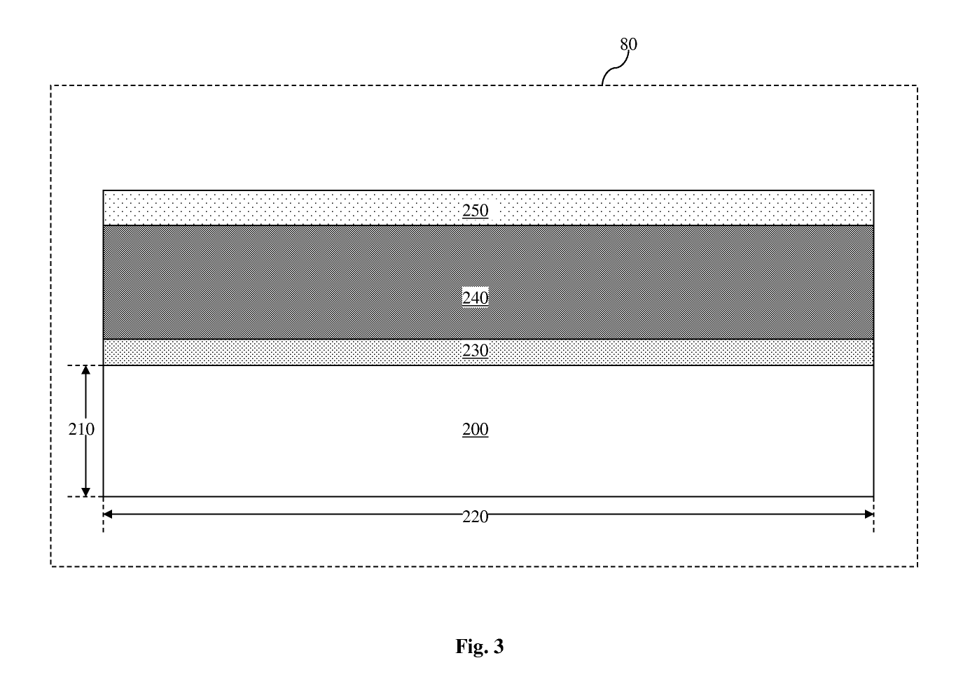

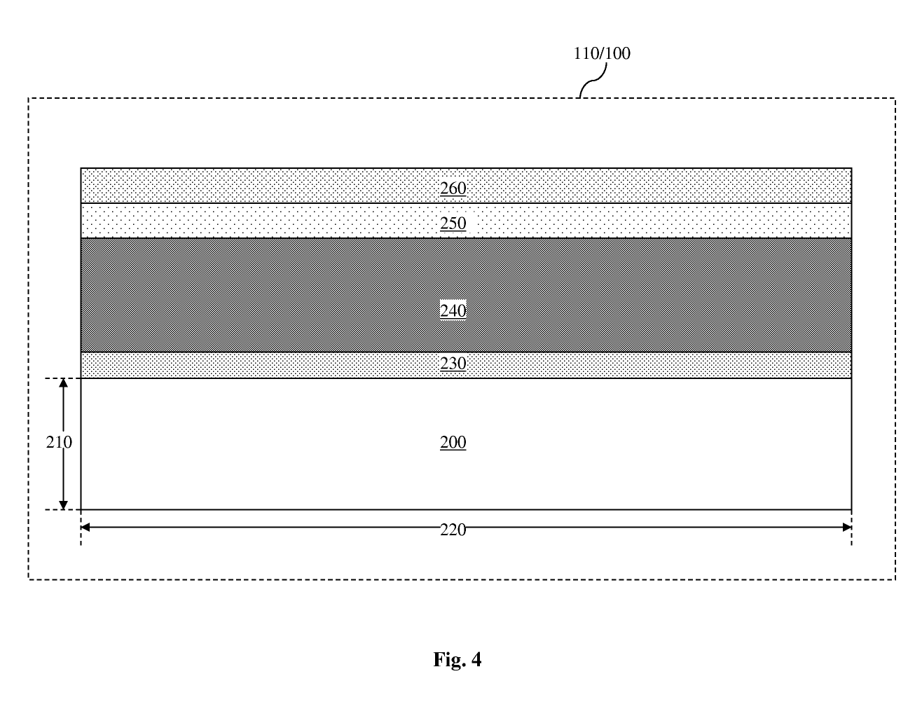

FIGS. 3 to 4 are diagrammatic fragmentary cross-sectional side views of a semiconductor device at various fabrication stages according to various aspects of the present disclosure. It is understood that FIGS. 2 to 6 have been simplified for a better understanding of the inventive concepts of the present disclosure, and that other processes may be performed before, during, or after the fabrication stages shown in FIGS. 3 to 4.

Referring to FIG. 3, a wafer 200 is provided. In the embodiment shown, the wafer 200 includes a silicon material and may be referred to as a silicon wafer 200 or a silicon substrate 200. The silicon wafer 200 has a thickness 210. In an embodiment, the thickness 210 is in a range from about 300 microns (um) to about 3000 um. The silicon wafer 200 is also approximately circular (from a top view) and has a diameter 220. In an embodiment, the diameter is in a range from about 4 inches to about 14 inches.

The silicon wafer 200 is loaded into the semiconductor fabrication tool 50 through the loading module 60 (shown in FIG. 2). The silicon wafer 200 is then moved to the transfer module 120. The transfer module 120 subsequently moves the silicon wafer 200 into the deposition module 80 (which includes a MOCVD chamber and is thereafter referred to as a MOCVD module 80). The MOCVD module 80 first forms a buffer layer 230 over the silicon wafer 200. The buffer layer 230 may include a plurality of thin layers of aluminum nitride or aluminum gallium nitride. These thin layers of aluminum nitride or aluminum gallium nitride may each be as thin as a few nanometers (nm) or tens of nanometers. The buffer layer 230 is formed at a high temperature that is in a range from about 800 degrees Celsius to about 1400 degrees Celsius.

Thereafter, the MOCVD module 80 forms a III-V family layer 240 over the buffer layer 230. In an embodiment, the III-V family layer 250 includes gallium nitride. The gallium nitride layer is formed at a high temperature that is in a range from about 800 degrees Celsius to about 1400 degrees Celsius. The gallium nitride layer may also be either N-type or P-type.

The MOCVD module 80 then forms an aluminum gallium nitride layer 250 over the buffer layer 230. The aluminum gallium nitride layer 250 has a chemical formula AlₓGa₁₋ₓN, where x is in a range from about 0.25 to 0.3. The aluminum gallium nitride layer 250 is formed at a high temperature that is in a range from about 800 degrees Celsius to about 1400 degrees Celsius. The aluminum gallium nitride layer 250 may also be either N-type or P-type.

After the aluminum gallium nitride layer 250 is formed, the silicon wafer 200 is taken out of the MOCVD module 80 and transferred to the deposition module 110 (which includes a LPCVD chamber and is thereafter referred to as the LPCVD module 110) by the transfer module 120. As discussed above, the transfer module 120 is substantially free of oxygen and silicon, and in an embodiment is filled with nitrogen at a pressure less or equal to the atmospheric pressure. The transfer module 120 is substantially free of oxygen to ensure no oxidation of the wafer will occur while the wafer 200 is inside the transfer module 120. Had the transfer module contained oxygen inside its chamber, the oxygen may react with the gallium nitride or the aluminum gallium nitride material on the wafer 200 and form a gallium oxide material (Ga₂O₃). This gallium oxide material is undesirable, because it may lead to the degradation of a two-dimensional electron gas (2DEG) when a transistor (to be formed) on the wafer 200 is in operation. In other words, gallium oxide adversely affects the electrical performance of semiconductor devices formed on the wafer 200. Therefore, the semiconductor tool 50 is designed specifically to substantially eliminate the presence of oxygen inside the transfer module 120 so as to prevent the formation of gallium oxide on the wafer.

Also, silicon would be considered a dopant for a III-V family layer (such as a gallium nitride layer), thereby making the III-V family layer not as pure as it should be. Hence, this is one of the reasons why the transfer module 120 is designed to contain substantially no silicon either. In addition, the fact that the transfer module 120 has pressure less or equal to the atmospheric pressure also offer flexibility advantages in terms of wafer handling. If the robot of the transfer module 120 picks up a wafer by Bernoulli's principle, the transfer module 120 can set its internal pressure to be at the atmospheric pressure. If the robot picks up the wafer by vacuum principle, the transfer module 120 can set its internal pressure to be either at or less than the atmospheric pressure.

Referring to FIG. 4, after the wafer 200 is transferred to the LPCVD module 110, a passivation layer 260 is formed over the aluminum gallium nitride layer 250 using the LPCVD module 110. The passivation layer 260 includes a silicon nitride material in one embodiment. In other embodiments, the passivation layer 260 may include a silicon oxide material or a silicon oxy-nitride material. The passivation layer 260 protects the surface of the wafer 200 and the layers formed thereon. Also, in an alternative embodiment, the passivation layer 260 may be formed using the deposition module 100 (which include a PECVD chamber).

Additional fabrication processes may be performed on the wafer 200 to finish the fabrication of semiconductor devices thereon. For example, source and drain regions may be formed by one or more doping processes. Gate structures may be formed between the source and drain regions. Conductive contacts may be formed on the source and drain regions and the gate. An interconnect structure may be formed to establish electrical connections between semiconductor devices formed on the wafer 200 and external devices. The interconnect structure may include a plurality of interconnect layers (also referred to as metal layers) that each contain a plurality of metal lines. These metal lines are interconnected together by vias. Thereafter, the wafer 200 may undergo probe testing, final testing, wafer dicing, and packaging processes. Furthermore, it is understood a plurality of types of semiconductor devices may be fabricated using the III-V family layer. For example, these semiconductor devices include, but are not limited to, high power devices, light-emitting diode (LED) devices, radio-frequency (RF) devices, and high electron mobility transistor (HEMT) devices.

The embodiments of the present disclosure discussed above offer advantages over existing methods. It is understood, however, that other embodiments may offer different advantages, and that no particular advantage is required for any embodiment. One of the advantages is that the MOCVD module 80 is integrated into the semiconductor fabrication tool 50. In existing semiconductor fabrication methodologies, the MOCVD deposition chamber is a standalone tool. Thus, after the formation of a III-V family layer and before the subsequent formation of a passivation layer over the III-V family layer, the wafer is usually taken out of the MOCVD deposition chamber and sent to a LPCVD deposition chamber. This not only increases queue time, but also exposes the wafer to oxygen in the air. As discussed before, the presence of oxygen may result in a gallium oxide material being formed on the wafer, which degrades 2DEG and is therefore undesirable.

In comparison, according to the embodiments described herein, when the wafer 200 finishes its processing inside the MOCVD module 80, it remains inside the semiconductor fabrication tool (specifically, inside the transfer module 120), there is no need to take the wafer out and risk oxygen exposure. And since the transfer module 120 is substantially free of oxygen, gallium oxide formation is substantially prevented. The fact that the transfer module 120 is substantially free of silicon also ensures that the wafer is not doped by silicon, thereby resulting in a relatively pure wafer. Furthermore, since the MOCVD module 80 is integrated into the semiconductor fabrication tool, the queue time before the wafer is transferred to the LPCVD module 110 (or the PECVD module 100) can be substantially reduced as well.

One of the broader forms of the present disclosure involves an apparatus. The apparatus includes a first deposition component that is operable to form a compound over a semiconductor wafer. The compound includes at least one of: a III-family element and a V-family element. The apparatus also includes a second deposition component that is operable to form a passivation layer over the compound. The apparatus also includes a transfer component that is operable to move the semiconductor wafer between the first and second deposition components. The transfer component encloses a space that contains substantially no oxygen and substantially no silicon. The loading component, the first and second deposition components, and the transfer component are all integrated into a single fabrication tool.

Another one of the broader forms of the present disclosure involves an apparatus that includes a semiconductor fabrication tool. The semiconductor fabrication tool includes a loading module that is operable to load a silicon wafer into the semiconductor fabrication tool. The semiconductor fabrication tool also includes a first deposition module that is operable to form a III-V family layer over the silicon wafer. The semiconductor fabrication tool also includes a second deposition module that is operable to form a dielectric passivation layer over the III-V family layer. The semiconductor fabrication tool also includes a transfer module that is directly coupled to the loading module, the first deposition module, and the second deposition module. A silicon content and an oxygen content are approximately zero inside the transfer module.

Yet another one of the broader forms of the present disclosure involves a method. The method includes forming a III-V family layer over a silicon wafer in a first deposition module. The method includes moving the silicon wafer to a second deposition module through a transfer module. The transfer module encloses a space that is substantially free of oxygen and silicon. The method includes forming a passivation layer over the III-V family layer in the second deposition module.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. An apparatus, comprising:
a first deposition component that is operable to form a compound over a semiconductor wafer, the compound including at least one of: a III-family element and a V-family element, wherein the first deposition component includes a metal-organic chemical vapor deposition (MOCVD) chamber;
a second deposition component that is operable to form a passivation layer over the compound, wherein the second deposition component includes one of: a low-pressure chemical vapor deposition (LPCVD) chamber and a plasma-enhanced chemical vapor deposition (PECVD) chamber; and
a transfer component that is operable to move the semiconductor wafer between the first and second deposition components, the transfer component enclosing a space that contains substantially no oxygen and substantially no silicon;
wherein the first and second deposition components and the transfer component are all integrated into a single fabrication tool.

2. The apparatus of claim 1, wherein the first deposition component is operable to form a gallium nitride layer as the compound.

3. The apparatus of claim 1, wherein the first deposition component is operable to form the compound over a silicon wafer, the silicon wafer being the semiconductor wafer.

4. The apparatus of claim 1, wherein the second deposition component is operable to form a silicon-containing dielectric layer over the compound, the silicon-containing dielectric layer being the passivation layer.

5. The apparatus of claim 1, wherein the first and second deposition components and the transfer component each include a sealable chamber.

6. (canceled)

7. The apparatus of claim 1, wherein the transfer component is directly coupled to each of the first and second deposition components.

8. The apparatus of claim 1, wherein the space enclosed by the transfer component is substantially filled with a nitrogen gas.

9. The apparatus of claim 1, further including: a loading component that is operable to load the semiconductor wafer into the fabrication tool.

10. An apparatus comprising a semiconductor fabrication tool that includes:
a loading module that is operable to load a silicon wafer into the semiconductor fabrication tool;
a first deposition module that is operable to form a III-V family layer over the silicon wafer, wherein the first deposition module includes a metal-organic chemical vapor deposition (MOCVD) module;
a second deposition module that is operable to form a dielectric passivation layer over the III-V family layer, wherein the second deposition module includes a low-pressure chemical vapor deposition (LPCVD) module; and
a transfer module that is directly coupled to the loading module, the first deposition module, and the second deposition module, wherein a silicon content and an oxygen content are approximately zero inside the transfer module, and wherein the loading module, the transfer module, and the first and second deposition modules are all integrated into a single tool.

11. (canceled)

12. The apparatus of claim 10, wherein:
the III-V family layer includes gallium nitride; and
the dielectric passivation layer includes one of: silicon nitride, silicon oxy-nitride, and silicon oxide.

13. The apparatus of claim 10, wherein the transfer module is substantially filled with a nitrogen gas and is at a pressure that is no greater than an atmospheric pressure.

14. The apparatus of claim 10, wherein the semiconductor fabrication tool is a semiconductor cluster tool, and wherein the loading module, the first and second deposition modules, and the transfer module each include a sealable chamber that can adjust a temperature, a pressure, and a gas composition inside the chamber.

15-20. (canceled)

21. A semiconductor fabrication system, comprising:
a metal-organic chemical vapor deposition (MOCVD) tool;
a low-pressure chemical vapor deposition (LPCVD) tool; and
a transfer tool directly coupled to both the MOCVD tool and the LPCVD tool;
wherein:
the MOCVD tool, the LPCVD tool, and the transfer tool are all integrated into a single apparatus; and
the transfer tool contains substantially no silicon nor oxygen.

22. The system of claim 21, wherein:
the MOCVD tool is operable to form a III-V group compound on a semiconductor wafer;
the LPCVD tool is operable to form a passivation material on the III-V group compound; and
the transfer tool is operable to transfer the semiconductor wafer between the MOCVD tool and the LPCVD tool.

23. The system of claim 22, wherein:
the III-V group compound contains gallium nitride; and
the passivation material includes silicon nitride, silicon oxy-nitride, or silicon oxide.

24. The system of claim 21, wherein the MOCVD tool and the LPCVD tool each include a sealable chamber.

25. The system of claim 21, further comprising: a plasma-enhanced chemical vapor deposition (PECVD) tool and a loading tool that are integrated into the single apparatus as the MOCVD tool, the LPCVD tool, and the transfer tool.

26. The system of claim 21, wherein the transfer tool is filled with a nitrogen gas.

27. The system of claim 21, further comprising: a controller for taking user input commands and operating the MOCVD tool, the LPCVD tool, and the transfer tool in response to the user input commands.

28. The system of claim 21, wherein a pressure inside the MOCVD tool and a pressure inside the LPCVD tool are each close to vacuum.
